(19) United States
(12) Patent Application Publication
(10) Pub. No.: US 2026/0223559 A1
(43) Pub. Date: Jul. 30, 2026

(54) DISPLAY PANEL AND ELECTRONIC DEVICE INCLUDING THE SAME

(71) Applicant: Samsung Display Co., Ltd., Yongin-si (KR)

(72) Inventors: KIKYUNG YOUK, Yongin-si (KR); SEUNGSUE RYU, Yongin-si (KR); JAEHAK LEE, Yongin-si (KR); DAEHYUK IM, Yongin-si (KR); SUNG-WOON IM, Yongin-si (KR)

(21) Appl. No.: 19/438,950

(22) Filed: Jan. 2, 2026

(30) Foreign Application Priority Data
Jan. 24, 2025 (KR) 10-2025-0011335

(51) Int. Cl. H10K 59/131

(52) U.S. Cl. CPC H10K 59/131

(57) ABSTRACT

A display panel includes an insulating layer, first and second pixels, a first signal line connected to the first pixel and including a first pad portion not above the insulating layer, a second signal line connected to the second pixel and including a second pad portion above the insulating layer, a first signal pad connected to the first signal line, and including a first-first conductive pattern contacting the first pad portion, a first insulating pattern thereabove, and a second-first conductive pattern above the first insulating pattern and connected to the first-first conductive pattern, and a second signal pad connected to the second signal line, and including a first-second conductive pattern contacting the second pad portion, a second insulating pattern thereabove and having a height less than a height of the first insulating pattern, and a second-second conductive pattern above the second insulating pattern and connected to the first-second conductive pattern.

### CROSS-REFERENCE TO RELATED APPLICATION

The present application claims priority to, and the benefit of, Korean Patent Application No. 10-2025-0011335, filed on January 24, 2025, in the Korean Intellectual Property Office, the entire disclosure of which is incorporated herein by reference.

### BACKGROUND

### 1. Field

The present disclosure relates to a pad area of a display panel, and an electronic device including the same.

### 2. Description of the Related Art

Various display devices applied to multimedia devices, such as televisions, mobile phones, tablet computers, navigation devices, and game devices, are being developed. As an input device for the display devices, a keyboard or a mouse is used. In addition, the display devices includes an input sensor, such as a touch panel, as their input device.

The display device includes a display area that is activated in response to electrical signals. The display device senses external inputs applied thereto through the display area, and displays images to provide information to a user.

The display device includes a display panel and a circuit board. The display device is connected to a main board via the circuit board. A driving chip or a film on which the driving chip is mounted is located on the display device. The driving chip or the film on which the driving chip is mounted is bonded to the display panel using an anisotropic conductive film (ACF), although a high pressure condition may be suitable during the bonding.

### SUMMARY

The present disclosure provides a display panel with reduced bonding defect of signal pads.

The present disclosure provides an electronic device including the display panel with reduced bonding defect of the signal pads.

Embodiments of the present disclosure provide a display panel including a base layer, at least one insulating layer above the base layer and including a first insulating layer, a first pixel above the base layer, a second pixel above the base layer, a first signal line electrically connected to the first pixel and including a first pad portion that is not above the first insulating layer, a second signal line electrically connected to the second pixel and including a second pad portion that is above the first insulating layer, a first signal pad connected to the first signal line, and including a first-first conductive pattern contacting the first pad portion, a first insulating pattern above the first-first conductive pattern, and a second-first conductive pattern above the first insulating pattern and connected to the first-first conductive pattern, and a second signal pad connected to the second signal line, and including a first-second conductive pattern contacting the second pad portion, a second insulating pattern above the first-second conductive pattern and having a height that is less than a height of the first insulating pattern, and a second-second conductive pattern above the second insulating pattern and connected to the first-second conductive pattern.

The first pad portion may be electrically connected to the first-first conductive pattern via a first contact hole defined through the at least one insulating layer, wherein the second pad portion is electrically connected to the first-second conductive pattern via a second contact hole defined through the at least one insulating layer.

The first signal pad and the second signal pad may be arranged in a same row and spaced apart from each other.

A portion of the first insulating layer may be between the first pad portion and the first-first conductive pattern.

A difference between the height of the first insulating pattern and the height of the second insulating pattern may be equal to a thickness of the first insulating layer.

The first insulating layer may have a thickness that is greater than or equal to about 1200 angstroms and less than or equal to about 1800 angstroms.

The display panel may further include a third pixel above the base layer, a third signal line electrically connected to the third pixel and including a third pad portion, and a third signal pad connected to the third signal line and including a first-third conductive pattern contacting the third pad portion, a third insulating pattern above the first-third conductive pattern and having a height that is greater than the height of the second insulating pattern, and a second-third conductive pattern above the third insulating pattern and connected to the first-third conductive pattern, wherein the at least one insulating layer further includes a second insulating layer that is under the third pad portion and that is not under the second pad portion.

The first signal pad and the second signal pad may extend in one direction when viewed in a plane, wherein the first insulating pattern is provided as a plurality of first insulating patterns spaced apart from each other in the one direction, and wherein the second insulating pattern is provided as a plurality of second insulating patterns spaced apart from each other in the one direction.

The first pad portion may be electrically connected to the first-first conductive pattern via a first contact hole defined through the at least one insulating layer and having a portion between the first insulating pattern and the first-first conductive pattern in plan view, wherein the second pad portion is electrically connected to the first-second conductive pattern via a second contact hole defined through the at least one insulating layer and having a portion between the second insulating pattern and the first-second conductive pattern in plan view.

The first insulating pattern may be inside the first-first conductive pattern in plan view, wherein the second insulating pattern is inside the first-second conductive pattern in plan view.

A length of a lower surface of the first insulating pattern may be greater than a length of an upper surface of the first insulating pattern, wherein a length of a lower surface of the second insulating pattern is greater than a length of an upper surface of the second insulating pattern.

A side surface of the first insulating pattern may have a slant shape and may contact the second-first conductive pattern.

The display panel of claim 1 may further include an input sensor above the second-first conductive pattern and the second-second conductive pattern.

Embodiments of the present disclosure provide an electronic device including an electronic component including a first bump and a second bump, and a display panel electrically connected to the electronic component, and including a base layer, at least one insulating layer above the base layer and including a first insulating layer, a first pixel above the base layer, a second pixel above the base layer, a first signal line electrically connected to the first pixel and including a first pad portion that is not above the first insulating layer, a second signal line electrically connected to the second pixel and including a second pad portion that is above the first insulating layer, a first signal pad connected to the first signal line, and including a first-first conductive pattern contacting the first pad portion, a first insulating pattern above the first-first conductive pattern, and a second-first conductive pattern above the first insulating pattern and connected to the first-first conductive pattern and to the first bump, and a second signal pad connected to the second signal line, and including a first-second conductive pattern contacting the second pad portion, a second insulating pattern above the first-second conductive pattern and having a height that is less than a height of the first insulating pattern, and a second-second conductive pattern above the second insulating pattern and connected to the first-second conductive pattern and to the second bump.

A height at which the second-first conductive pattern contacts the first bump may be substantially equal to a height at which the second-second conductive pattern contacts the second bump.

A difference between the height of the first insulating pattern and the height of the second insulating pattern may be equal to a thickness of the first insulating layer.

The first pad portion may be electrically connected to the first-first conductive pattern via a first contact hole defined through the at least one insulating layer, wherein the second pad portion is electrically connected to the first-second conductive pattern via a second contact hole defined through the at least one insulating layer.

The first signal pad and the second signal pad may extend in one direction in plan view, wherein the first insulating pattern is provided as a plurality of first insulating patterns spaced apart from each other in the one direction, and wherein the second insulating pattern is provided as a plurality of second insulating patterns spaced apart from each other in the one direction.

The first pad portion may be electrically connected to the first-first conductive pattern via a first contact hole defined through the at least one insulating layer and having a portion between the first insulating pattern and the first-first conductive pattern in plan view, wherein the second pad portion is electrically connected to the first-second conductive pattern via a second contact hole defined through the at least one insulating layer and having a portion between the second insulating pattern and the first-second conductive pattern in plan view.

A length of a lower surface of the first insulating pattern may be greater than a length of an upper surface of the first insulating pattern, wherein a length of a lower surface of the second insulating pattern is greater than a length of an upper surface of the second insulating pattern.

According to the above, the display panel and the electronic device include the first pad portion of the first signal line and the second pad portion of the second signal line that are located at different layers. Due to the difference between the height of the first insulating pattern located above the first pad portion of the first signal line and the height of the second insulating pattern located above the second pad portion of the second signal line, the positional difference between the first pad portion and the second pad portion is reduced. Consequently, the electronic component and the signal pads are bonded to each other under uniform pressure in a bonding process. As a result, the signal pads have uniform resistance, and thus, electrical reliability is improved.

### BRIEF DESCRIPTION OF THE DRAWINGS

FIG. 1 is a block diagram of an electronic device according to one or more embodiments of the present disclosure;

FIG. 2 is a schematic view of various electronic devices according to embodiments of the present disclosure;

FIG. 3 is an assembled perspective view of an electronic device according to one or more embodiments of the present disclosure;

FIG. 4 is an exploded perspective view of an electronic device according to one or more embodiments of the present disclosure;

FIG. 5 is a cross-sectional view of a display device according to one or more embodiments of the present disclosure;

FIG. 6 is a plan view of a display panel according to one or more embodiments of the present disclosure;

FIG. 7 is a cross-sectional view of a display panel according to one or more embodiments of the present disclosure;

FIG. 8 is an exploded perspective view of a pad area of a display device according to one or more embodiments of the present disclosure;

FIG. 9 is an enlarged plan view of a pad area of a display panel according to one or more embodiments of the present disclosure;

FIG. 10 is an enlarged plan view of signal pads according to one or more embodiments of the present disclosure;

FIG. 11A is a cross-sectional view of a pad area according to one or more embodiments of the present disclosure;

FIG. 11B is a cross-sectional view of a pad area according to one or more embodiments of the present disclosure;

FIG. 11C is a cross-sectional view of an electronic device according to one or more embodiments of the present disclosure;

FIG. 12A is an exploded perspective view of a pad area of a display panel according to one or more embodiments of the present disclosure;

FIG. 12B is a cross-sectional view of a pad area according to one or more embodiments of the present disclosure; and

FIGS. 13A to 13E are cross-sectional views of processes of a method of manufacturing a display panel according to one or more embodiments of the present disclosure.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing one or more embodiments corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature’s relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component (e.g., an apparatus, a device, a circuit, a wire, an electrode, a terminal, a conductive film, etc.) is referred to as being “formed on,” “on,” “connected to,” or “(operatively, functionally, or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a transistor, a resistor, an inductor, a capacitor, a diode and/or the like. Accordingly, a connection is not limited to the connections illustrated in the drawings or the detailed description and may also include other types of connections. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XY, YZ, and XZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When "C to D" is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are only used to distinguish one element, member, component, region, area, layer, section, or portion from another element, member, component, region, area, layer, section, or portion. Thus, a first element, component, region, layer, or section described below could be termed a second element, component, region, layer, or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/- 5 % of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ± 30%, 20%, 10%, 5% of the stated value. Further, the use of “may” when describing embodiments of the present disclosure refers to “one or more embodiments of the present disclosure.” Furthermore, the expression “being the same” may mean “being substantially the same.” In other words, the expression “being the same” may include a range that can be tolerated by those of ordinary skill in the art. The other expressions may also be expressions from which “substantially” has been omitted.

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

A display device according to embodiments may be applied to various electronic devices. The electronic device according to embodiments may include the display device and may further include modules or devices with additional functions other than the display device.

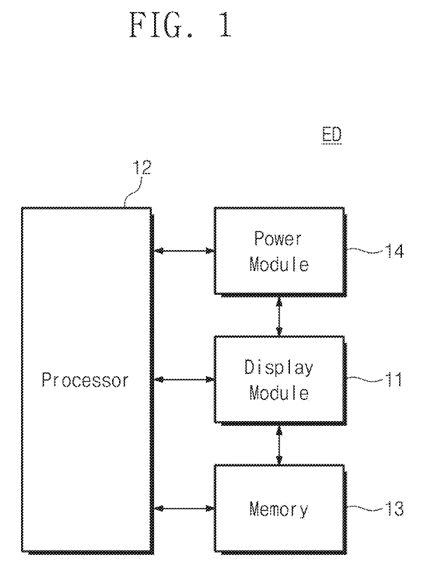

FIG. 1 is a block diagram of the electronic device according to one or more embodiments of the present disclosure. Referring to FIG. 1, the electronic device ED may include a display module 11, a processor 12, a memory 13, and a power module 14.

The processor 12 may include at least one of a central processing unit (CPU), an application processor (AP), a graphics processing unit (GPU), a communication processor (CP), an image signal processor (ISP), or a controller.

The memory 13 may store data information suitable for the operation of the processor 12 or the display module 11. When the processor 12 executes an application stored in the memory 13, an image data signal and/or an input control signal may be transmitted to the display module 11, and the display module 11 may process the received signals to output image information through a display screen.

The power module 14 may include a power supply module, such as a power adapter or a battery device, and a power conversion module that converts power supplied by the power supply module to generate power suitable for the operation of the electronic device ED.

At least one of the components of the electronic device ED may be included in a display device. In addition, among individual modules that are functionally included within a single module, some may be included in the display device while others may be provided separately from the display device. As an example, the display device may include the display module 11, and the processor 12, the memory 13, and the power module 14 may be provided as separate devices within the electronic device ED and may not be included in the display device.

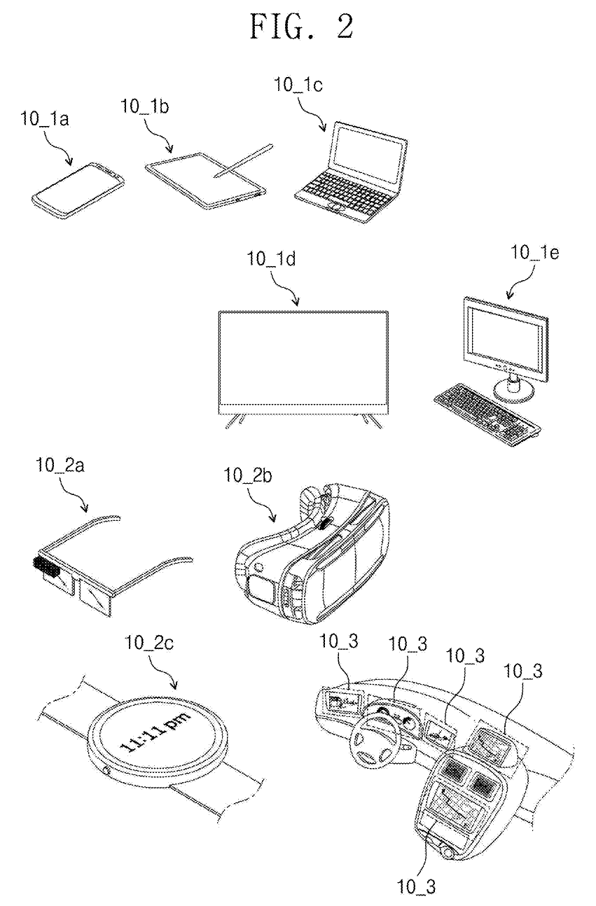

FIG. 2 is a view showing electronic devices according to embodiments of the present disclosure.

Referring to FIG. 2, various electronic devices to which the display device according to embodiments is applied may include an electronic device for displaying images, such as a smartphone 10_1a, a tablet PC 10_1b, a laptop computer 10_1c, a television 10_1d, a desktop monitor 10_1e, etc., a wearable electronic device including a display module, such as a smart glasses 10_2a, a head-mounted display 10_2b, a smartwatch 10_2c, etc., or an in-vehicle electronic device ED_3 including a display module, such as an instrument panel, a center fascia, a dashboard-mounted center information display (CID), a room mirror display, etc.

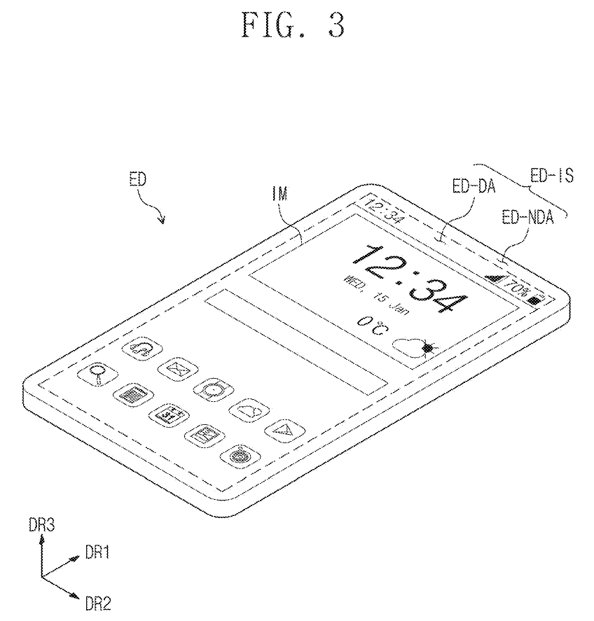

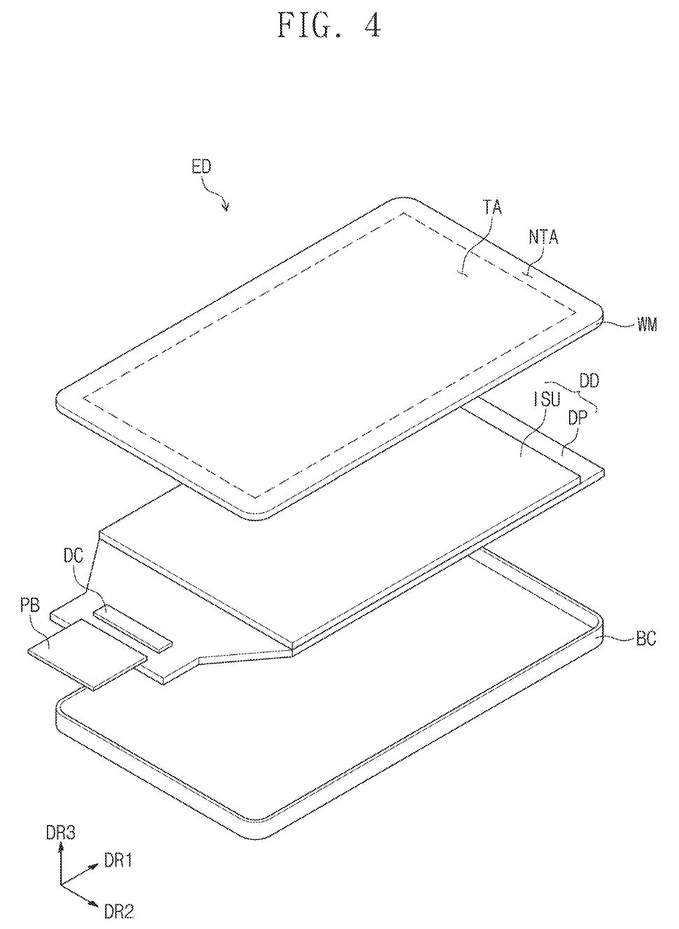

FIG. 3 is an assembled perspective view of the electronic device ED according to one or more embodiments of the present disclosure. FIG. 4 is an exploded perspective view of the electronic device ED according to one or more embodiments of the present disclosure.

FIGS. 3 and 4 show a smartphone as an example of the electronic device ED. Referring to FIG. 3, the electronic device ED may display an image IM through a display surface ED-IS. FIG. 3 shows icon images as an example of the image IM. The display surface ED-IS may be substantially parallel to a plane defined by a first direction DR1 and a second direction DR2. A third direction DR3 may indicate a normal line direction of the display surface ED-IS (e.g., a thickness direction of the electronic device ED). In the following descriptions, an expression “when viewed in a plane" or "in a plane” may refer to a state of being viewed in the third direction DR3. Front (or upper) and rear (or lower) surfaces of layers or units described below may be distinguished from each other with respect to the third direction DR3.

The display surface ED-IS may include a display area ED-DA through which the image IM is displayed, and a non-display area ED-NDA adjacent to the display area ED-DA. The non-display area ED-NDA may be an area in which the image IM is not displayed. However, the present disclosure should not be limited thereto or thereby, and the non-display area ED-NDA may be defined adjacent to one side of the display area ED-DA or may be omitted.

Referring to FIG. 4, the electronic device ED may include a window WM, a display device DD, and a housing BC. The housing BC may accommodate the display device DD and may be coupled to the window WM. In one or more embodiments, the electronic device ED may further include other electronic modules accommodated in the housing BC and electrically connected to a display device DD. For instance, the electronic device ED may further include a main board, a circuit module mounted on the main board, a camera module, a power module, and the like.

The window WM may be located on the display device DD and may transmit the image provided from the display device DD to the outside. The window WM may include a transmission area TA and a non-transmission area NTA. The transmission area TA may overlap the display area ED-DA of FIG. 3, and may have a shape corresponding to that of the display area ED-DA.

The non-transmission area NTA may overlap the non-display area ED-NDA (refer to FIG. 3), and may have a shape corresponding to that of the non-display area ED-NDA (refer to FIG. 3). The non-transmission area NTA may have a relatively low light transmittance compared to that of the transmission area TA.

The display device DD may generate the image and may sense an external input. The display device DD may include the display panel DP and an input sensor ISU. In one or more embodiments, the display device DD may further include an anti-reflective member located on the input sensor ISU. The anti-reflective member may include a polarizer and a retarder or may include a color filter and a black matrix.

The display panel DP may be a light-emitting type display panel, although it should not be particularly limited. For instance, the display panel DP may be an organic light-emitting display panel or an inorganic light-emitting display panel. A light-emitting layer of the organic light-emitting display panel may include an organic light-emitting material. A light-emitting layer of the inorganic light-emitting display panel may include a quantum dot, a quantum rod, or a nano-LED. Hereinafter, the organic light-emitting display panel will be described as an example of the display panel DP.

The input sensor ISU may include one of a capacitive sensor, an optical sensor, an ultrasonic sensor, and an electromagnetic induction sensor. The input sensor ISU may be formed on the display panel DP through a continuous process or may be attached to an upper portion of the display panel DP using an adhesive layer after being separately manufactured.

The display device DD may further include a driving chip DC and a circuit board PB. FIG. 4 shows a structure in which the driving chip DC is mounted on the display panel DP, although it should not be limited thereto or thereby. The driving chip DC may generate a driving signal suitable for an operation of the display panel DP in response to a control signal provided from the circuit board PB. The circuit board PB bonded to the display panel DP may be bent and may be located on a rear surface of the display panel DP. The circuit board PB may be located at one end of a base layer described later and may be electrically connected to a circuit element layer described later.

In one or more embodiments, the display device DD may further include a connection circuit board on which the driving chip DC is mounted and the circuit board PB. The circuit board PB may apply signals to the display panel DP through the connection circuit board, and the connection circuit board may include a flexible film and may be bent.

In the display device DD, the display panel DP may be partially bent such that the driving chip DC may face downward. A portion of the non-display area ED-NDA (refer to FIG. 3) of the display panel DP may be bent. However, the bent portion should not be limited thereto or thereby, and the circuit board PB may be bent.

In the above descriptions, the smartphone is described as the electronic device ED, although, in the present disclosure, it may be sufficient for the electronic device ED to include two or more bonded electronic components. The display panel DP and the driving chip DC mounted on the display panel DP may correspond to different electronic components, and these alone may constitute the electronic device ED. Alternatively, only the display panel DP and the circuit board PB connected to the display panel DP may constitute the electronic device ED, and only the main board and the electronic module mounted on the main board may constitute the electronic device ED. Hereinafter, the display device DD and the electronic device ED will be described with a focus on the bonding structure between the display panel DP and the driving chip DC mounted on the display panel DP.

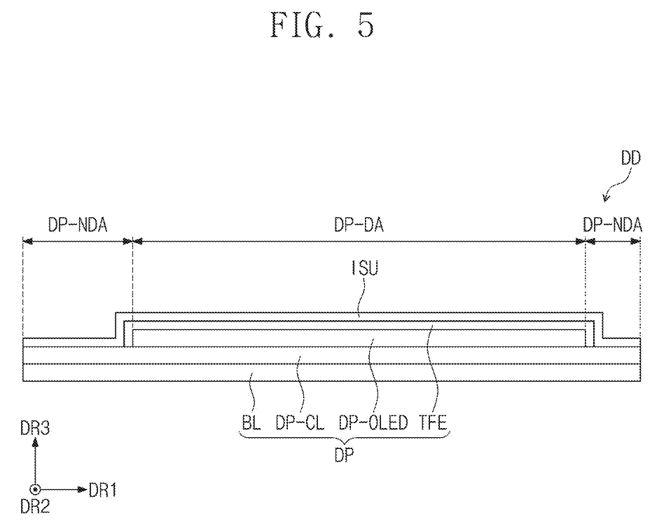

FIG. 5 is a cross-sectional view of the display device DD according to one or more embodiments of the present disclosure.

Referring to FIG. 5, the display panel DP may include the base layer BL, the circuit element layer DP-CL located on the base layer BL, a display element layer DP-OLED, and a thin film encapsulation layer TFE. The input sensor ISU may be located on the thin film encapsulation layer TFE.

The display panel DP may include a display area DP-DA and a non-display area DP-NDA. The display area DP-DA of the display panel DP may correspond to the display area ED-DA shown in FIG. 3 or the transmission area TA shown in FIG. 4, and the non-display area DP-NDA may correspond to the non-display area ED-NDA shown in FIG. 3 or the non-transmission area NTA shown in FIG. 4.

The base layer BL may include the display area DP-DA and the non-display area DP-NDA around the display area DP-DA. The base layer BL may include a synthetic resin film. The base layer BL may have a multi-layer structure. For instance, the base layer BL may have a three-layer structure of a synthetic resin layer, an inorganic layer, and a synthetic resin layer. For example, the synthetic resin layer may include a polyimide-based resin, although it should not be limited thereto or thereby. The synthetic resin layer may include at least one of an acrylic-based resin, a methacrylic-based resin, a polyisoprene-based resin, a vinyl-based resin, an epoxy-based resin, a urethane-based resin, a cellulose-based resin, a siloxane-based resin, a polyamide-based resin, or a perylene-based resin. The base layer BL may include a glass substrate, a metal substrate, or an organic/inorganic composite material substrate.

The circuit element layer DP-CL may include at least one insulating layer and/or a circuit element. The insulating layer may include at least one inorganic layer and at least one organic layer. The circuit element may include signal lines and a pixel-driving circuit. This will be described in detail later.

The display element layer DP-OLED may include an organic light-emitting element. The display element layer DP-OLED may further include an organic layer such as a pixel definition layer.

The thin film encapsulation layer TFE may be located on the display element layer DP-OLED to cover the display element layer DP-OLED. The thin film encapsulation layer TFE may protect pixels from moisture, oxygen, and a foreign substance. However, it should not be limited thereto or thereby, and according to one or more embodiments, the thin film encapsulation layer TFE may further include an additional insulating layer. For instance, the thin film encapsulation layer TFE may further include an optical insulating layer to control a refractive index.

The input sensor ISU may be located directly on the display panel DP. The input sensor ISU may be formed through a continuous process with the display panel DP, although the present disclosure should not be limited thereto or thereby. According to one or more embodiments, the input sensor ISU may be provided as an individual panel and then may be coupled to the display panel DP by an adhesive layer. According to one or more embodiments, the input sensor ISU may be omitted.

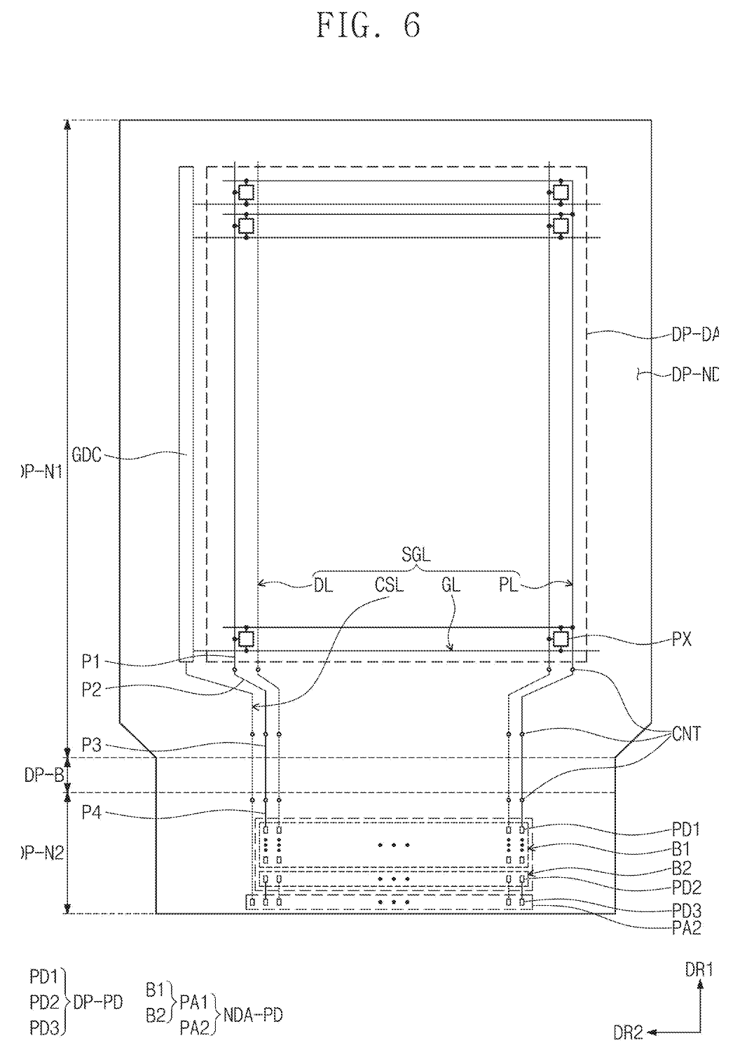

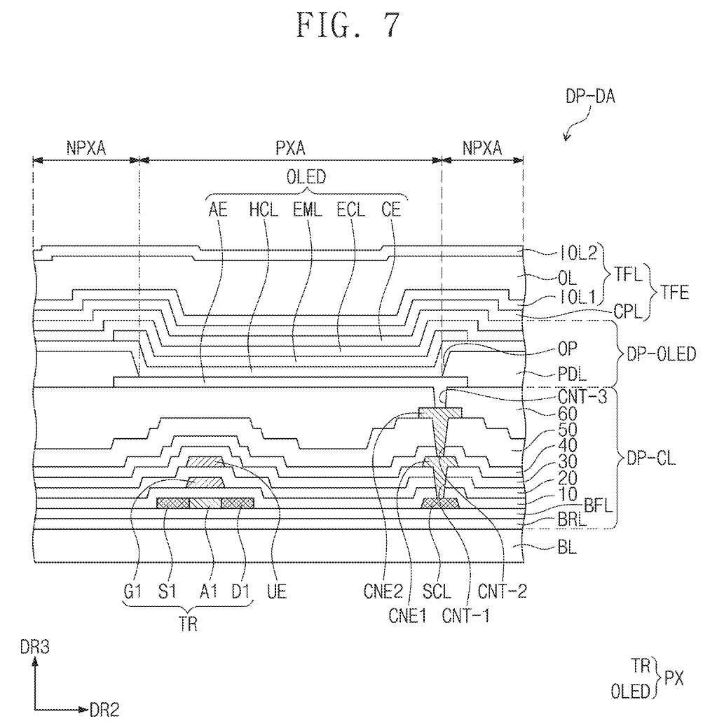

FIG. 6 is a plan view of the display panel DP according to one or more embodiments of the present disclosure. FIG. 7 is a cross-sectional view of the display panel DP according to one or more embodiments of the present disclosure. In more detail, FIG. 7 is a cross-sectional view of the display area DP-DA of the display panel DP.

As shown in FIG. 6, the display panel DP may include the display area DP-DA and the non-display area DP-NDA when viewed in the plane. The non-display area DP-NDA may be defined along an edge of the display area DP-DA. The display area DP-DA and the non-display area DP-NDA of the display panel DP may correspond to the display area DP-DA and the non-display area DP-NDA of the display device DD shown in FIG. 5.

The display panel DP may include a first non-bending area DP-N1, a second non-bending area DP-N2, and a bending area DP-B. Areas of the display panel DP and areas of the display device DD that correspond to each other do not necessarily have to be the same as each other and may vary depending on the structure/design of the display panel DP.

Referring to FIG. 6, the display panel DP may include a plurality of pixels PX, a gate-driving circuit GDC, a plurality of signal lines SGL, and a plurality of signal pads PD.

The pixels PX may be arranged in the display area DP-DA. Each of the pixels PX may include a light-emitting element and a pixel-driving circuit connected to the light-emitting element. According to one or more embodiments, the light-emitting element may be an organic light-emitting element. The gate-driving circuit GDC, the signal lines SGL, and the pixel-driving circuit may be included in the circuit element layer DP-CL shown in FIG. 5.

The gate-driving circuit GDC may sequentially output gate signals to a plurality of gate lines GL described later. The gate-driving circuit GDC may include a transistor formed through the same process as a transistor of the pixel PX, e.g., a low temperature polycrystalline silicon (LTPS) process or a low temperature polycrystalline oxide (LTPO) process. The display panel DP may further include another driving circuit that applies a light emission control signal to the pixels PX.

The signal lines SGL may include the gate lines GL, data lines DL, a power line PL, and a control signal line CSL. Each of the gate lines GL may be connected to a corresponding pixel PX among the pixels PX, and each of the data lines DL may be connected to a corresponding pixel PX among the pixels PX. The power line PL may be connected to the pixels PX. The control signal line CSL may provide control signals to the gate-driving circuit GDC.

The display panel DP may include the signal pads DP-PD connected to ends of the signal lines SGL. In the non-display area DP-NDA, an area in which the signal pads DP-PD are arranged may be defined as a pad area NDA-PD.

The signal pads DP-PD may include first pads PD1, second pads PD2, and third pads PD3. An area in which the first pads PD1 and the second pads PD2 are arranged may be referred to as a first pad area PA1, and an area in which the third pads PD3 are arranged may be referred to as a second pad area PA2.

The first pad area PA1 may be an area bonded to the driving chip DC (refer to FIG. 4), and the second pad area PA2 may be an area bonded to the circuit board PB (refer to FIG. 4). The first pad area PA1 may include a first area B1 in which the first pads PD1 are arranged and a second area B2 in which the second pads PD2 are arranged.

The first pad area PA1 and the second pad area PA2 may be spaced apart from each other in the first direction DR1. The first pad area PA1 may be closer to the display area DP-DA than the second pad area PA2 is, the second pad area PA2 may be spaced apart from the display area DP-DA, and the first pad area PA1 may be located between the second pad area PA2 and the display area DP-DA.

Each of the first pads PD1 may be connected to a corresponding data line DL among the data lines DL. The second pads PD2 may be connected to the third pads PD3 via connection signal lines. Multiple pad rows may be arranged in the first area B1.

Referring to FIG. 7, the display area DP-DA may include a light-emitting area PXA and a non-light-emitting area NPXA. Each of the pixels PX may include the transistor TR and the light-emitting element OLED.

As an example, FIG. 7 shows one transistor TR, although the present disclosure should not be limited thereto or thereby. The pixel PX may include seven transistors and at least one capacitor, and the seven transistors and the capacitor may be electrically connected to each other. However, the number of the transistors and the number of the capacitors that form the pixel PX should not be particularly limited.

The display panel DP may include a plurality of insulating layers, a semiconductor pattern, a conductive pattern, and a signal line. An insulating layer, a semiconductor layer, and a conductive layer may be formed by a coating or depositing process. Then, the insulating layer, the semiconductor layer, and the conductive layer may be selectively patterned through a photolithography process. Accordingly, the semiconductor pattern, the conductive pattern, and the signal line included in the circuit element layer DP-CL and the display element layer DP-OLED may be formed.

According to one or more embodiments, the circuit element layer DP-CL may include a barrier layer BRL, a buffer layer BFL, first, second, third, fourth, fifth, and sixth insulating layers 10, 20, 30, 40, 50, and 60, the transistor TR, the connection signal line SCL, an upper electrode UE, a first connection electrode CNE1, and a second connection electrode CNE2.

At least one inorganic layer may be formed on an upper surface of the base layer BL. The inorganic layer may be formed in multiple layers. The barrier layer BRL may be located on the base layer BL. The buffer layer BFL may be located on the barrier layer BRL. Each of the barrier layer BRL and the buffer layer BFL may be an inorganic layer.

The semiconductor pattern may be located on the buffer layer BFL. The semiconductor pattern may include polysilicon, although it should not be limited thereto or thereby. According to one or more embodiments, the semiconductor pattern may include amorphous silicon or metal oxide.

FIG. 7 shows only a portion of the semiconductor pattern, and the semiconductor pattern may be further located in other areas of the pixel PX when viewed in the plane. The semiconductor pattern may be arranged with a corresponding rule over pixels. The semiconductor pattern may have different electrical properties depending on whether it is doped or not. The semiconductor pattern may include a first region and a second region. The first region may be doped with an N-type dopant or a P-type dopant. A P-type transistor may include a doped region doped with the P-type dopant.

The first region may have a conductivity higher than that of the second region and may substantially serve as an electrode or signal line. The second region may have a low doping concentration or may be undoped, and the second region may substantially correspond to an active (or a channel) of a transistor. A portion of the semiconductor pattern may be the active of the transistor, another portion of the semiconductor pattern may be a source or a drain of the transistor, and the other portion of the semiconductor pattern may be a connection electrode or a connection signal line.

As shown in FIG. 7, a source S1, an active A1, and a drain D1 of the transistor TR may be formed from the semiconductor pattern. FIG. 7 shows a portion of the connection signal line SCL formed from the semiconductor pattern. According to one or more embodiments, the connection signal line SCL may be electrically connected to the drain of one of the transistors in the pixel PX.

The first insulating layer 10 may be located on the buffer layer BFL. The first insulating layer 10 may cover the semiconductor pattern. The first insulating layer 10 may commonly overlap the pixels. A gate G1 of the transistor TR may be located on the first insulating layer 10. The gate G1 may be a portion of a metal pattern. The gate G1 may overlap the active A1. The gate G1 may be used as a mask in a process of doping the semiconductor pattern.

The second insulating layer 20 may be located on the first insulating layer 10, and may cover the gate G1. The second insulating layer 20 may commonly overlap the pixels. The upper electrode UE may be located on the second insulating layer 20. The upper electrode UE may overlap the gate G1 of the transistor TR. The upper electrode UE may be a portion of a metal pattern. A portion of the gate G1 and the upper electrode UE overlapping the portion of the gate G1 may define a capacitor.

The third insulating layer 30 may be located on the second insulating layer 20, and may cover the upper electrode UE. The first connection electrode CNE1 located on the third insulating layer 30 may be connected to the connection signal line SCL via a contact hole CNT-1 defined through the first, second, and third insulating layers 10, 20, and 30.

The fourth insulating layer 40 may be located on the third insulating layer 30 to cover the first connection electrode CNE1. The first to fourth insulating layers 10, 20, 30, and/or 40 may be an inorganic layer and/or organic layer and may have a single-layer or multi-layer structure.

According to one or more embodiments, a first connection electrode may be located on the fourth insulating layer 40 and may be covered by the fifth insulating layer 50. According to one or more embodiments, the circuit element layer DP-CL may include a first connection electrode located on the third insulating layer 30 and covered by the fourth insulating layer 40 and a first connection electrode located on the fourth insulating layer 40 and covered by the fifth insulating layer 50.

The fifth insulating layer 50 may be located on the fourth insulating layer 40. The fifth insulating layer 50 may be an inorganic layer. The second connection electrode CNE2 may be located on the fifth insulating layer 50. The second connection electrode CNE2 may be connected to the first connection electrode CNE1 via a contact hole CNT-2 defined through the fourth insulating layer 40 and the fifth insulating layer 50.

The sixth insulating layer 60 may be located on the fifth insulating layer 50 and may cover the second connection electrode CNE2. The sixth insulating layer 60 may be an organic layer. A first electrode AE may be located on the sixth insulating layer 60. The first electrode AE may be connected to the second connection electrode CNE2 via a contact hole CNT-3 defined through the sixth insulating layer 60.

The circuit element layer DP-CL may include a plurality of connection electrodes connected to the transistors, and some of the connection electrodes may be located at different layers from each other. In one or more embodiments, the first connection electrode CNE1 may extend and may be connected to the transistor TR. Positions of the connection electrodes should not be particularly limited.

The display element layer DP-OLED may include the pixel definition layer PDL and the light-emitting element OLED. A pixel opening OP may be defined through the pixel definition layer PDL, and at least a portion of the first electrode AE may be exposed through the pixel opening OP of the pixel definition layer PDL. The light-emitting area PXA may be defined to correspond to a portion of the first electrode AE exposed through the pixel opening OP.

A hole control layer HCL may be commonly located in the light-emitting area PXA and the non-light-emitting area NPXA. The hole control layer HCL may include a hole transport layer and/or a hole injection layer. A light-emitting layer EML may be located on the hole control layer HCL. The light-emitting layer EML may be located in an area corresponding to the pixel opening OP. That is, the light-emitting layer EML may be separately formed for each of the pixels. However, the present disclosure should not be limited thereto or thereby, and the light-emitting layer EML may be commonly formed in the pixels PX using an open mask.

An electron control layer ECL may be located on the light-emitting layer EML. The electron control layer ECL may include an electron transport layer and/or an electron injection layer. The hole control layer HCL and the electron control layer ECL may be commonly located over the pixels. A second electrode CE may be located on the electron control layer ECL. The second electrode CE may have an integral shape, and may be commonly located in the pixels.

The thin film encapsulation layer TFE may be located on the second electrode CE. The thin film encapsulation layer TFE may include a capping layer CPL protecting the display element layer DP-OLED and an upper insulating layer TFL located on the capping layer CPL. The upper insulating layer TFL may include a first inorganic layer IOL1, an organic layer OL, and a second inorganic layer IOL2.

Referring to FIG. 6 again, the signal lines including portions located at different layers in the display panel DP are shown as an example. The signal lines SGL of the display panel DP may include first, second, third, and fourth portions P1, P2, P3, and P4. The first to fourth portions P1 to P4 may be connected to each other through contact holes CNT. Some of the first to fourth portions P1 to P4 may be located at different respective layers, and some of the first to fourth portions P1 to P4 may be located at the same layer. As an example, one of more portions of the first to fourth portions P1 to P4 may be located at the same layer as the gate G1 (refer to FIG. 7), and the other portions of the first to fourth portions P1 to P4 may be located at the same layer as the first connection electrode CNE1 (refer to FIG. 7) or the second connection electrode CNE2 (refer to FIG. 7).

The contact holes CNT may penetrate at least one insulating layer located between two corresponding portions among the first to fourth portions P1 to P4 to connect the two portions.

According to one or more embodiments, the first portion P1 and the second portion P2, which overlap the first non-bending area DP-N1, may be located at the same layer as the second connection electrode CNE2 (refer to FIG. 7), and the third portion P3 overlapping the bending area DP-B may be located at the same layer as the first connection electrode CNE1 (refer to FIG. 7). The fourth portion P4 overlapping the second non-bending area DP-N2 may be located at the same layer as the gate G1 (refer to FIG. 7). However, the fourth portion P4 may be located at the same layer as the upper electrode UE (refer to FIG. 7) according to the corresponding pixel.

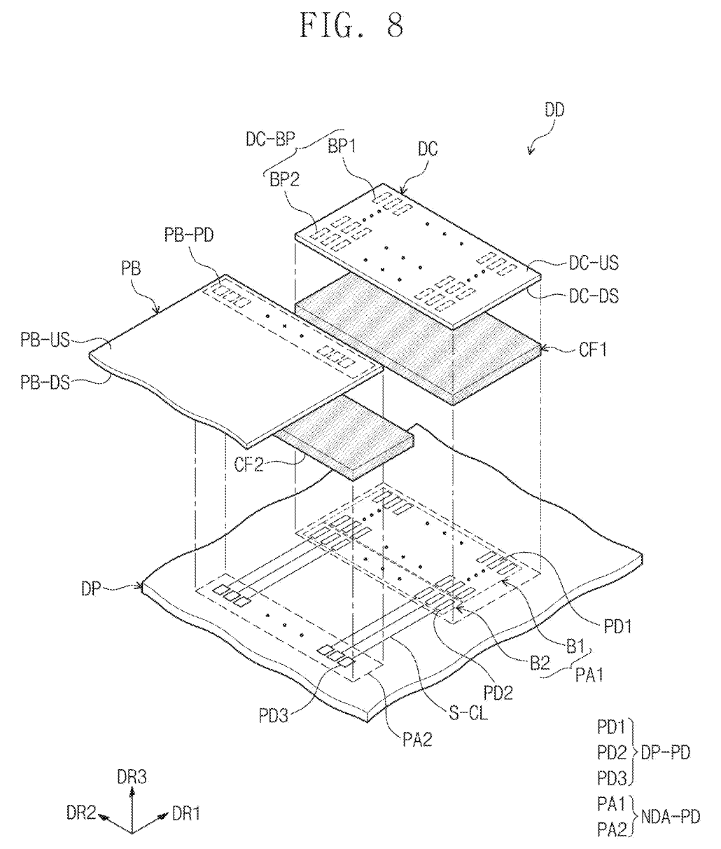

FIG. 8 is an exploded perspective view of the pad area NDA-PD of the display device DD according to one or more embodiments of the present disclosure. As an example, in FIG. 8, the driving chip DC and the circuit board PB are illustrated separately from the display panel DP. In FIG. 8, detailed descriptions of the same elements as those in FIG. 6 will be omitted.

The first pad area PA1 may be an area overlapping the driving chip DC, and the second pad area PA2 may be an area overlapping the circuit board PB. The first pad area PA1 may include the first area B1 in which the first pads PD1 are arranged, and the second area B2 in which the second pads PD2 are arranged. The first pad area PA1 and the second pad area PA2 may be spaced apart from each other in the first direction DR1. A plurality of pad rows may be arranged in the first area B1. According to one or more embodiments, at least five or more pad rows may be arranged in the first area B1.

The circuit board PB may include a plurality of circuit pads PB-PD. The circuit pads PB-PD may be arranged in the second direction DR2. The circuit pads PB-PD of the circuit board PB may be connected to the third pads PD3 of the second pad area PA2.

The driving chip DC may be bonded to the first pad area PA1 by a first adhesive layer CF1. The circuit board PB may be bonded to the second pad area PA2 by a second adhesive layer CF2. The first adhesive layer CF1 and the second adhesive layer CF2 may include a synthetic resin with an adhesive property. Each of the first adhesive layer CF1 and the second adhesive layer CF2 may be a non-conductive film. That is, the first adhesive layer CF1 and the second adhesive layer CF2 may include only the synthetic resin with the adhesive property, and may not include, or may omit, conductive balls.

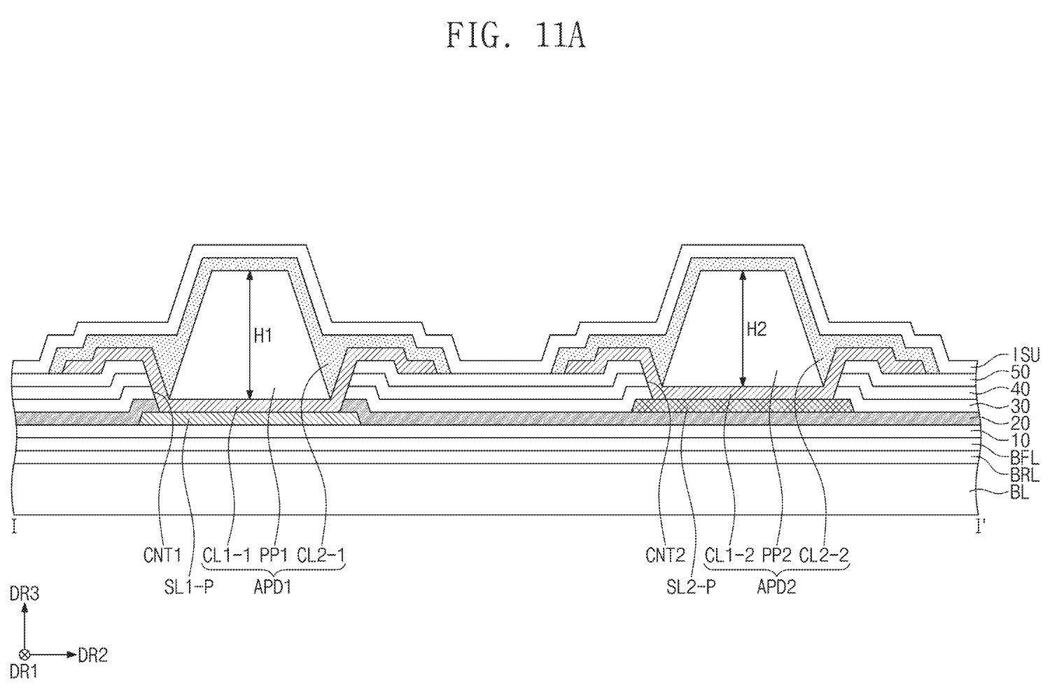

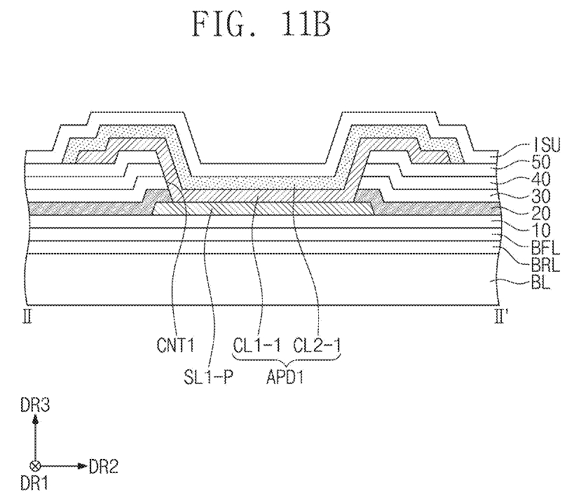

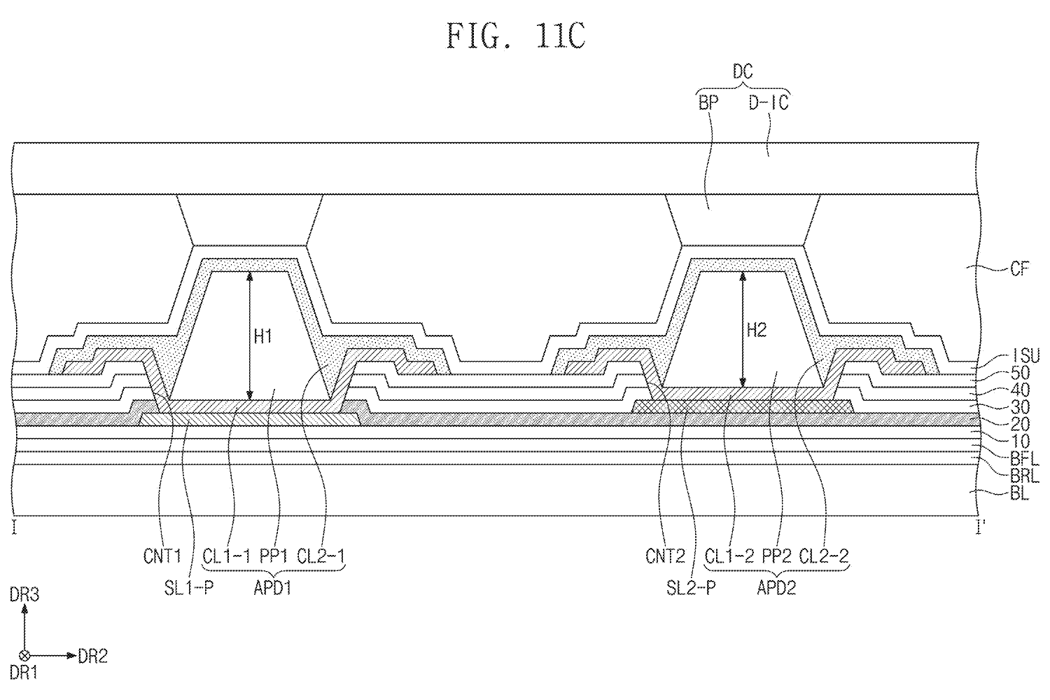

The driving chip DC may include a driving integrated circuit D-IC of FIG. 11c and driving bumps DC-BP. The driving chip DC may include an upper surface DC-US and a lower surface DC-DS, and the lower surface DC-DS may face the first and second pads PD1 and PD2. The driving bumps DC-BP may be located on the lower surface DC-DS of the driving chip DC.

The driving bumps DC-BP may include first bumps BP1 electrically connected to the first pads PD1, respectively, and second bumps BP2 electrically connected to the second pads PD2, respectively. The first bumps BP1 may be arranged in the second direction DR2, and the second bumps BP2 may be spaced apart from the first bumps BP1 in the first direction DR1, and may be arranged in the second direction DR2.

The driving chip DC may receive first signals from the outside via the second pads PD2 and the second bumps BP2. The driving chip DC may apply second signals, which are generated based on the first signals, to the first pads PD1 via the first bumps BP1. As an example, the driving chip DC may include a data driving circuit. The first signal may be an image signal that is a digital signal provided from the outside, and the second signal may be a data signal that is an analog signal. The driving chip DC may generate an analog voltage corresponding to a grayscale value of the image signal. The data signal may be applied to the pixel PX via the data line DL shown in FIG. 6.

In FIG. 8, for the convenience of explanation, a shape of the driving bumps DC-BP when viewed in the plane is illustrated in a dotted line in the upper surface DC-US of the driving chip DC, although the first bumps BP1 and the second bumps BP2 may protrude from the lower surface DC-DS of the driving chip DC, and may be exposed to the outside.

The circuit board PB may be located on the display panel DP. The circuit board PB may be located on the third pads PD3. The circuit board PB may include an upper surface PB-US and a lower surface PB-DS, and the lower surface PB-DS may face the third pads PD3. The circuit board PB may include the circuit pads PB-PD electrically connected to the third pads PD3. The circuit pads PB-PD may be located on the lower surface PB-DS of the circuit board PB. The circuit pads PB-PD may be arranged in the second direction DR2. The circuit board PB may provide image signals, driving voltages, and other control signals to the driving chip DC.

In one or more embodiments, each of the driving chip DC and the circuit board PB may be located on the connection circuit board. As an example, the driving chip DC may be mounted on a lower portion of the connection circuit board, and the circuit board PB may be mounted on an upper portion of the connection circuit board. The driving chip DC and the circuit board PB may be electrically connected to the display panel DP through the connection circuit board.

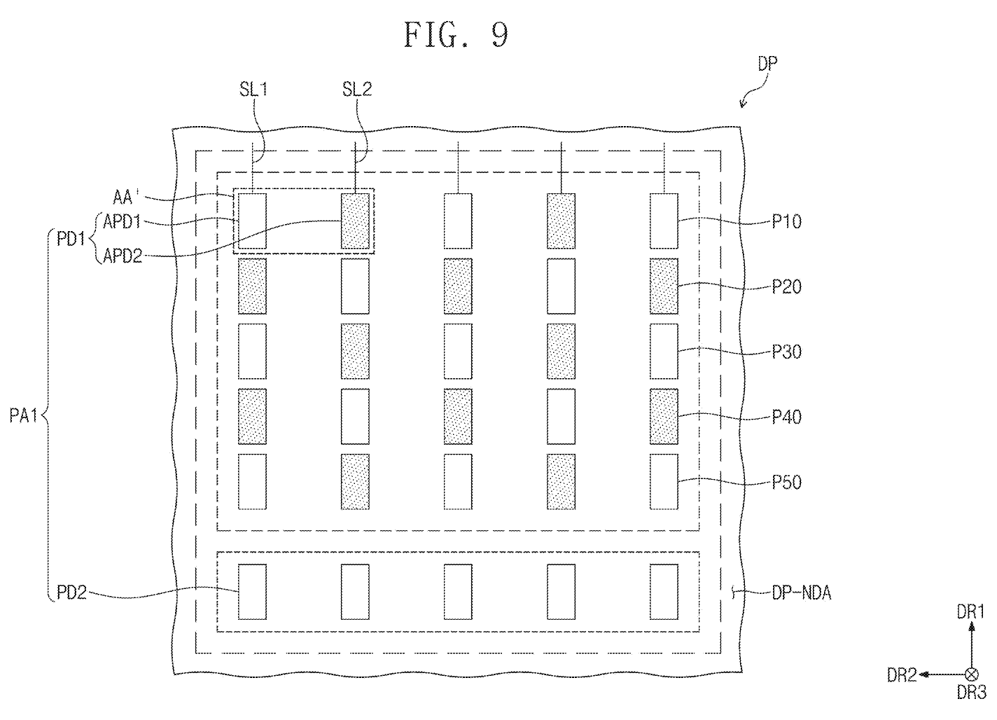

FIG. 9 is an enlarged plan view of the pad area of the display panel DP according to one or more embodiments of the present disclosure. FIG. 9 is an enlarged plan view of the first pad area PA1 of the display panel DP according to one or more embodiments of the present disclosure.

The first pads PD1 and the second pads PD2 may be arranged in the first pad area PA1. Each of the first pads PD1 and the second pads PD2 may include a plurality of pads spaced apart from each other in the second direction DR2. The first pads PD1 may define a plurality of input rows P10, P20, P30, P40, and P50 extending in the second direction DR2.

FIG. 9 shows the first pads PD1 arranged in five rows by five columns as an example, although the first pads PD1 may include at least five or more input rows. As the resolution of the display panel DP increases, the number of the pixels PX (refer to FIG. 6) may increase, and the number of the first pads PD1 used to control each pixel may also increase.

According to one or more embodiments of the present disclosure, the first pads PD1 may include a first signal pad APD1 and a second signal pad APD2. Each of the first pads PD1 may be connected to corresponding signal lines SGL (refer to FIG. 6) among the signal lines SGL. As an example, the first signal pad APD1 may be connected to a first signal line SL1, and the second signal pad APD2 may be connected to a second signal line SL2. The first signal line SL1 may be electrically connected to a corresponding first pixel among the pixels PX (refer to FIG. 6), and the second signal line SL2 may be electrically connected to a corresponding second pixel among the pixels PX (refer to FIG. 6).

According to one or more embodiments, the first signal line SL1 and the second signal line SL2 may be located at different layers in the first pad area PA1. As a pitch between the signal pads in a high-resolution display panel decreases, adjacent pads may be connected to the signal lines that are located at different layers. As shown in FIG. 9, a structure in which the first signal line SL1 is alternately arranged with the second signal line SL2 may be applied to each of the first pads PD1 in a first row P10. The structure in which the first signal line SL1 is alternately arranged with the second signal line SL2 may be applied to each of the first pads PD1 arranged in the same column.

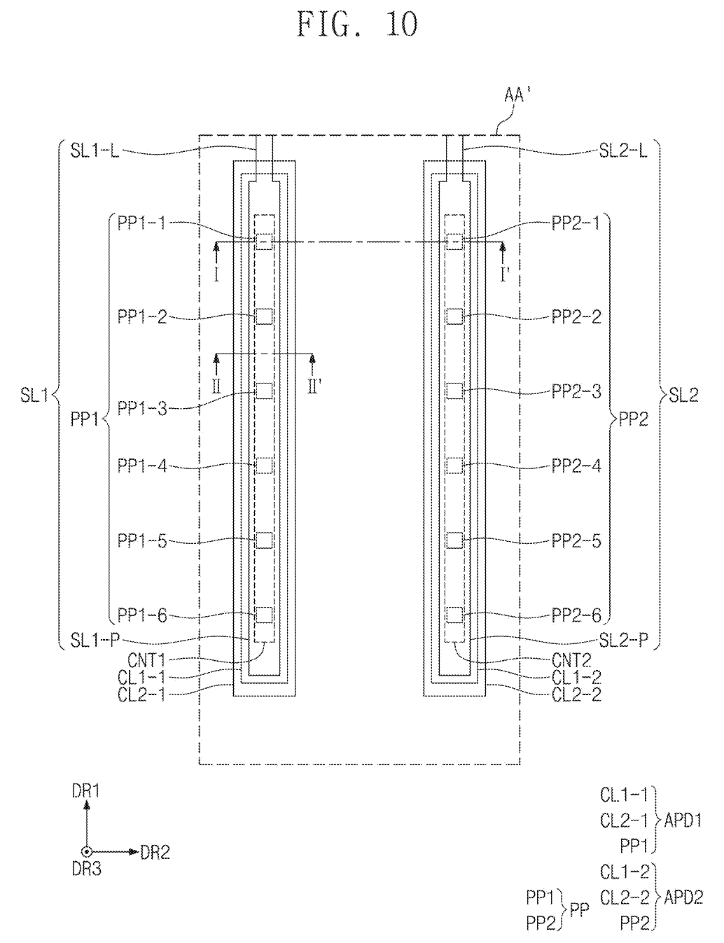

FIG. 10 is an enlarged plan view of the signal pads according to one or more embodiments of the present disclosure. FIG. 11A is a cross-sectional view of the pad area according to one or more embodiments of the present disclosure. FIG. 11B is a cross-sectional view of the pad area according to one or more embodiments of the present disclosure. FIG. 11C is a cross-sectional view of the electronic device according to one or more embodiments of the present disclosure. FIG. 11A is a cross-sectional view of the pad area taken along the line I-I’ of FIGS. 10, and FIG. 11B is a cross-sectional view of the pad area taken along the line II-II’ of FIG. 10. FIG. 11C is a cross-sectional view of the electronic device taken along the line I-I’ of FIG. 10.

FIG. 10 schematically shows the first signal pad APD1 and the second signal pad APD2, which correspond to an area AA’ of FIG. 9 when viewed in the plane. In FIG. 10, the first signal line SL1 may include a first line portion SL1-L and a first pad portion SL1-P, which have different respective widths, and the second signal line SL2 may include a second line portion SL2-L and a second pad portion SL2-P, which have different respective widths. A width of the first signal line SL1 and a width of the second signal line SL2 may refer to a length or width in the second direction DR2.

When viewed in the plane, each of the first pad portion SL1-P and the second pad portion SL2-P may have a shape extending in the first direction DR1. That is, a length in the first direction DR1 of the first pad portion SL1-P may be greater than a length in the second direction DR2 of the first pad portion SL1-P. Similarly, a length in the first direction DR1 of the second pad portion SL2-P may be greater than a length in the second direction DR2 second pad portion SL2-P.

Referring to FIGS. 10 and 11A, the first pad portion SL1-P of the first signal line SL1 may be located on the first insulating layer 10. The first pad portion SL1-P may be located at the same layer as the gate G1 shown in FIG. 7. That is, the first pad portion SL1-P may be formed through the same process as the gate G1, and may include the same material as the gate G1.

According to one or more embodiments, the first pad portion SL1-P of the first signal line SL1 may be located at a different layer from the second pad portion SL2-P of the second signal line SL2. The second pad portion SL2-P of the second signal line SL2 may be located on the second insulating layer 20. The second pad portion SL2-P of the second signal line SL2 may be located at the same layer as the upper electrode UE shown in FIG. 7. That is, the second pad portion SL2-P may be formed through the same process as the upper electrode UE, and may include the same material as the upper electrode UE.

According to one or more embodiments of the present disclosure, the first signal pad APD1 may include a first-first conductive pattern CL1-1, a first insulating pattern PP1, and a second-first conductive pattern CL2-1. The second signal pad APD2 may include a first-second conductive pattern CL1-2, a second insulating pattern PP2, and a second-second conductive pattern CL2-2. The first signal pad APD1 and the second signal pad APD2 may be spaced apart from each other along the second direction DR2 in the same pad row. Each of the first signal pad APD1 and the second signal pad APD2 may extend in the first direction DR1.

Referring to FIGS. 10 and 11A, the first-first conductive pattern CL1-1 may contact the first pad portion SL1-P. The first-first conductive pattern CL1-1 may be electrically connected to the first pad portion SL1-P via a first contact hole CNT1 defined through at least one insulating layer. The first-second conductive pattern CL1-2 may contact the second pad portion SL2-P, and the first-second conductive pattern CL1-2 may be electrically connected to the second pad portion SL2-P via a second contact hole CNT2 defined through at least one insulating layer.

The first-first conductive pattern CL1-1 and the first pad portion SL1-P may be distinguished from each other by multiple insulating layers located between the first-first conductive pattern CL1-1 and the first pad portion SL1-P. As an example, a portion of the second insulating layer 20 may be located on the first pad portion SL1-P, and may be located between the first pad portion SL1-P and the first-first conductive pattern CL1-1 (e.g., may be located between a portion of the first pad portion SL1-P and a portion of the first-first conductive pattern CL1-1). However, the second insulating layer 20 may not be located under (e.g., may be omitted from beneath) the first pad portion SL1-P. The third insulating layer 30, the fourth insulating layer 40, and the fifth insulating layer 50 may further be located between the first pad portion SL1-P and the first-first conductive pattern CL1-1 (e.g., between a portion of, such as an end of, the first pad portion SL1-P and a portion of the first-first conductive pattern CL1-1).

The first-second conductive pattern CL1-2 and the second pad portion SL2-P may be distinguished from each other by multiple insulating layers located between the first-second conductive pattern CL1-2 and the second pad portion SL2-P. As an example, the second insulating layer 20 may be located under the second pad portion SL2-P. As an example, the third insulating layer 30, the fourth insulating layer 40, and the fifth insulating layer 50 may be located between the first-second conductive pattern CL1-2 and the second pad portion SL2-P.

Referring to FIG. 10, when viewed in the plane (e.g., in plan view), the first contact hole CNT1 (e.g., a portion thereof) may be defined between the first insulating pattern PP1 (e.g., an end of the first insulating pattern PP1) and the first-first conductive pattern CL1-1 (e.g., a portion of the first-first conductive pattern CL1-1), and the second contact hole CNT2 (e.g., a portion thereof) may be defined between the second insulating pattern PP2 (e.g., an end of the second insulating pattern PP2) and the first-second conductive pattern CL1-2 (e.g., a portion of the first-second conductive pattern CL1-2). As shown in FIG. 10, the first-first conductive pattern CL1-1 may be connected to the first pad portion SL1-P through one first contact hole CNT1, although the present disclosure should not be limited thereto or thereby. According to one or more embodiments, the first-first conductive pattern CL1-1 may be connected to the first pad portion SL1-P through multiple contact holes defined between multiple first insulating patterns PP1 in the first direction DR1.

Referring to FIGS. 10 and 11A, the first insulating pattern PP1 may be located on the first-first conductive pattern CL1-1, and the second insulating pattern PP2 may be located on the first-second conductive pattern CL1-2. When viewed in the plane, the first insulating pattern PP1 may be located inside the first-first conductive pattern CL1-1 and inside the first contact hole CNT1. Similarly, the second insulating pattern PP2 may be located inside the first-second conductive pattern CL1-2 and inside the second contact hole CNT2 when viewed in the plane.

Referring to FIG. 10, the first insulating pattern PP1 may be provided in plural, and the first insulating patterns PP1 may be arranged in the first direction DR1. The first insulating patterns PP1 may include first-first to first-sixth insulating patterns PP1-1 to PP1-6, and the first-first to first-sixth insulating patterns PP1-1 to PP1-6 may be spaced apart from each other in the first direction DR1. The second insulating pattern PP2 may also be provided in plural, and the second insulating patterns PP2 may be arranged in the first direction DR1. The second insulating patterns PP2 may include second-first to second-sixth insulating patterns PP2-1 to PP2-6.

According to one or more embodiments, the insulating patterns PP1 and PP2 may include a polymer. The insulating patterns PP1 and PP2 may include a thermosetting polymer, although the present disclosure should not be limited thereto or thereby. According to one or more embodiments, the insulating patterns PP1 and PP2 may include a thermoplastic polymer.

Referring to FIGS. 10 and 11A, the first insulating pattern PP1 may be located on the first pad portion SL1-P, and the second insulating pattern PP2 may be located on the second pad portion SL2-P. The second insulating pattern PP2 may have a height H2 that is less than a height H1 of the first insulating pattern PP1. Accordingly, an upper surface of the second insulating pattern PP2 may be positioned at the same height as an upper surface of the first insulating pattern PP1.

A lower surface of the second insulating pattern PP2 may be positioned at a height that is greater than a lower surface of the first insulating pattern PP1 by a thickness of the second insulating layer 20. A difference between the height H2 of the second insulating pattern PP2 and the height H1 of the first insulating pattern PP1 may be the same as the thickness of the second insulating layer 20. The thickness of the second insulating layer 20 may be greater than or equal to about 1200Å and less than or equal to about 1800Å. The difference between the height H2 of the second insulating pattern PP2 and the height H1 of the first insulating pattern PP1 may be greater than or equal to about 1200 Å and less than or equal to about 1800Å.

The lower surface of the first insulating pattern PP1 may have a length that is greater than a length of the upper surface of the first insulating pattern PP1, and a length of the lower surface of the second insulating pattern PP2 may be greater than a length of the upper surface of the second insulating pattern PP2. A side surface of the first insulating pattern PP1 may have a slant shape, and the side surface of the first insulating pattern PP1 may contact the second-first conductive pattern CL2-1. That is, when the second-first conductive pattern CL2-1 is formed, a space between the side surface of the first insulating pattern PP1 and the first-first conductive pattern CL1-1 may be filled.

When viewed in the plane, the second-first conductive pattern CL2-1 may be located at an outside of the first-first conductive pattern CL1-1 and the first insulating pattern PP1, and the second-second conductive pattern CL2-2 may be located at an outside of the first-second conductive pattern CL1-2 and the second insulating pattern PP2. As shown in FIG. 11A, the second-first conductive pattern CL2-1 may contact the first-first conductive pattern CL1-1 in a portion that does not overlap the first insulating pattern PP1, and the second-second conductive pattern CL2-2 may contact the first-second conductive pattern CL1-2 in a portion that does not overlap the second insulating pattern PP2.

Referring to FIGS. 11A and 11C, the second-first conductive pattern CL2-1 may overlap the first insulating pattern PP1, and may protrude in the third direction DR3, and the second-second conductive pattern CL2-2 may overlap the second insulating pattern PP2, and may protrude in the third direction DR3. Due to the insulating patterns PP1 and PP2 with sufficient thickness in the third direction DR3, the driving chip DC may be bonded to the signal pads APD1 and APD2 without including conductive particles in an adhesive layer CF. Accordingly, electric shorts and/or open defects caused by agglomeration of conductive particles may be reduced, and thus, bonding reliability may be improved.

According to one or more embodiments, because the upper surface of the first insulating pattern PP1 is positioned at the same height as the upper surface of the second insulating pattern PP2, the second-first conductive pattern CL2-1 covering the upper surface of the first insulating pattern PP1 may also be positioned at the same height as the second-second conductive pattern CL2-2 covering the upper surface of the second insulating pattern PP2. Accordingly, in the bonding process of the display panel DP and the driving chip DC, the bump BP of the driving chip DC, the first signal pad APD1, and the second signal pad APD2 may receive a load of uniform pressure. The signal pads bonded with the uniform pressure may have uniform resistance, and thus, electrical reliability may be improved. In addition, because the signal pads are bonded with the uniform pressure, a bonding adhesion and mechanical stability may increase.

A height at which the second-first conductive pattern CL2-1 and its corresponding bump come into contact may be the same as a height at which the second-second conductive pattern CL2-2 and its corresponding bump come into contact.

The input sensor ISU may be located on the second-first conductive pattern CL2-1 and the second-second conductive pattern CL2-2. The input sensor ISU may be located on the thin film encapsulation layer TFE shown in FIG. 7, and may include at least one conductive pattern and at least one insulating pattern. The conductive pattern included in the input sensor ISU may be connected to each of the second-first conductive pattern CL2-1 and the second-second conductive pattern CL2-2. Because the input sensor ISU contacts the bump BP, the signal pads APD1 and APD2 may be electrically connected to the driving chip DC.

FIG. 11B is a cross-sectional view of the pad area taken along the line II-II’ of FIG. 10. In FIG. 11B, the first insulating pattern PP1 may not be located on the first-first conductive pattern CL1-1, and the first-first conductive pattern CL1-1 may be connected to the first pad portion SL1-P of the first signal line SL1 through the first contact hole CNT1. In addition, because the first insulating pattern PP1 is not located, or is omitted, the first-first conductive pattern CL1-1 and the second-first conductive pattern CL2-1 may contact each other at a center of the first pad portion SL1-P in the second direction DR2.

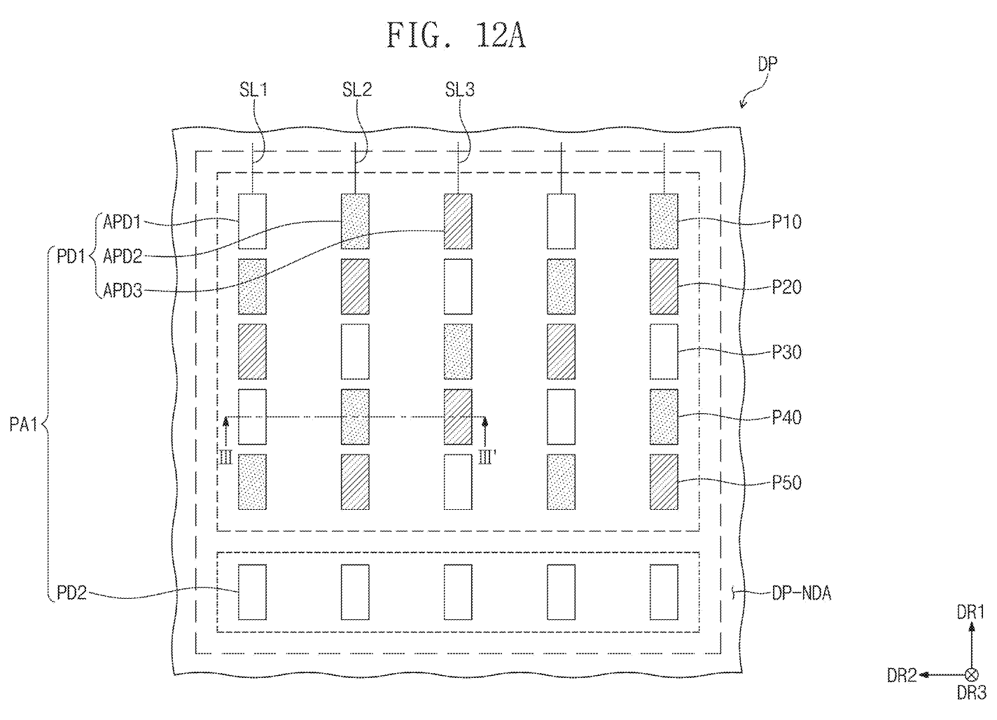

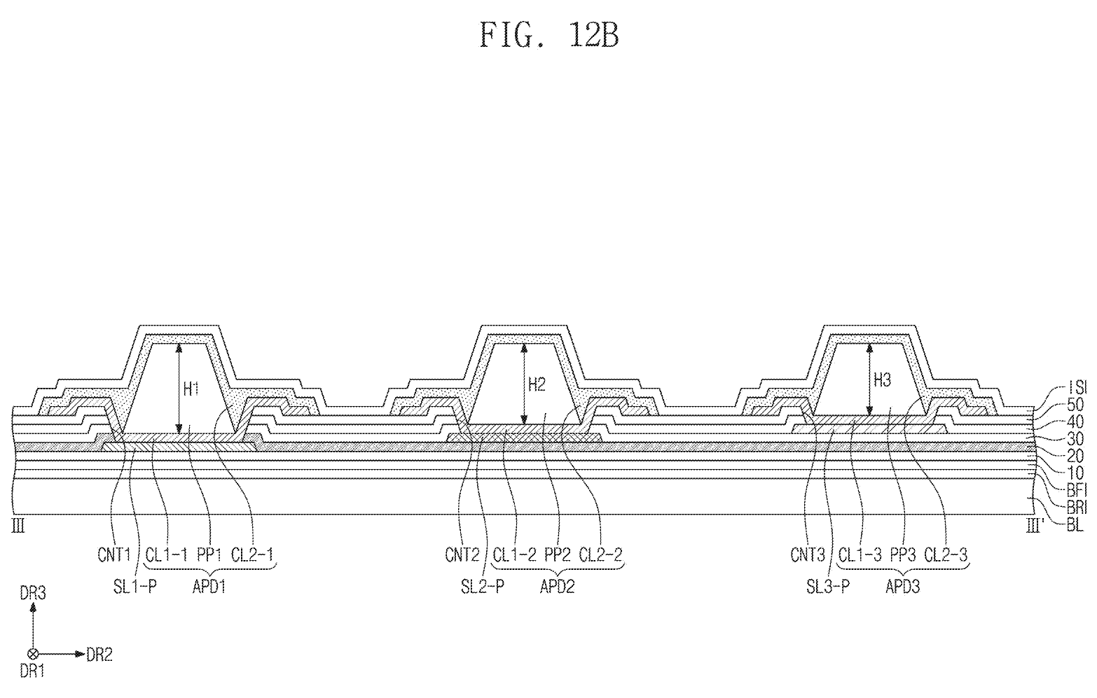

FIG. 12A is an exploded perspective view of a pad area of a display panel according to one or more embodiments of the present disclosure, and FIG. 12B is a cross-sectional view of the pad area according to one or more embodiments of the present disclosure. FIG. 12B is a cross-sectional view taken along the line III-III’ of FIG. 12A. In FIGS. 12A and 12B, the same reference numerals denote the same elements in FIGS. 9, 10, and 11A to 11C, and thus, detailed descriptions of the same elements will be omitted.

Referring to FIGS. 12A and 12B, the display panel DP may further include a third pixel, a third signal line SL3 electrically connected to the third pixel, and a third signal pad APD3 connected to the third signal line. The third signal line SL3 may include a third pad portion SL3-P. A third insulating layer 30 may not be located under (e.g., may be omitted from beneath) a second pad portion SL2-P, and may be located under the third pad portion SL3-P. The third signal pad APD3 may include a first-third conductive pattern CL1-3, a third insulating pattern PP3 located on the first-third conductive pattern CL1-3, and a second-third conductive pattern CL2-3 located on the third insulating pattern PP3 and connected to the first-third conductive pattern CL1-3.

As shown in FIG. 12B, the first-third conductive pattern CL1-3 may contact the third pad portion SL3-P, and the third pad portion SL3-P may be located at a different layer from the second pad portion SL2-P. The third pad portion SL3-P may be located at the same layer as the first connection electrode CNE1 shown in FIG. 7.

A lower surface of the third insulating pattern PP3, which contacts the first-third conductive pattern CL1-3, may be positioned at a height that is greater than a lower surface of a second insulating pattern PP2, which contacts a first-second conductive pattern CL1-2. The third insulating pattern PP3 may have a height H3 that is less than a height H2 of the second insulating pattern PP2, and thus, the second-third conductive pattern CL2-3 may be located at the same height as a second-second conductive pattern CL2-2.

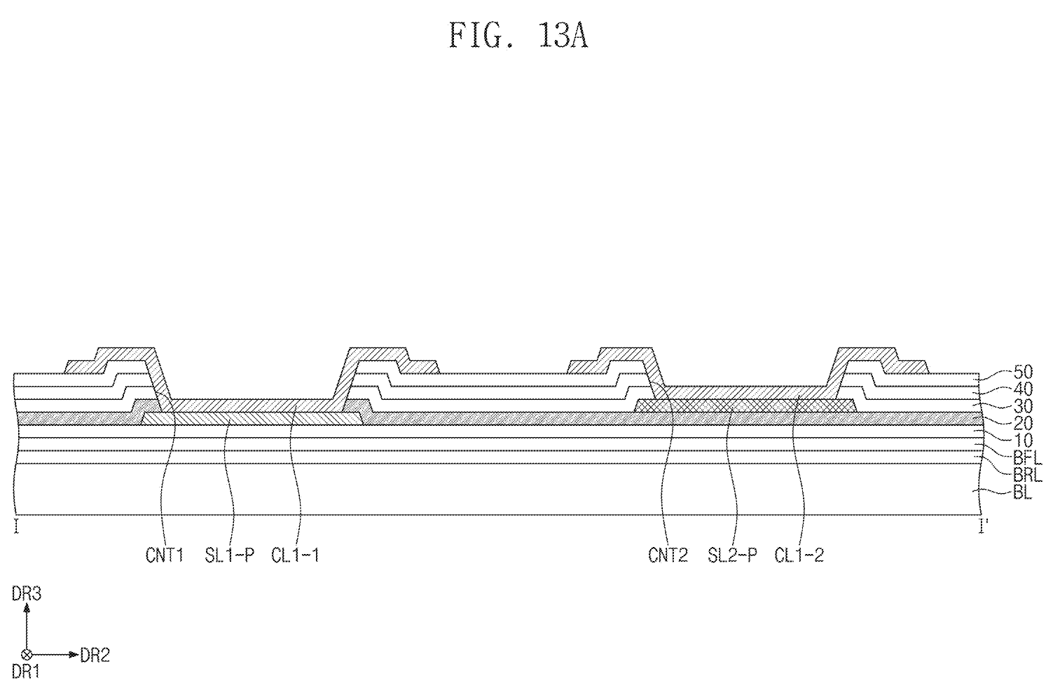

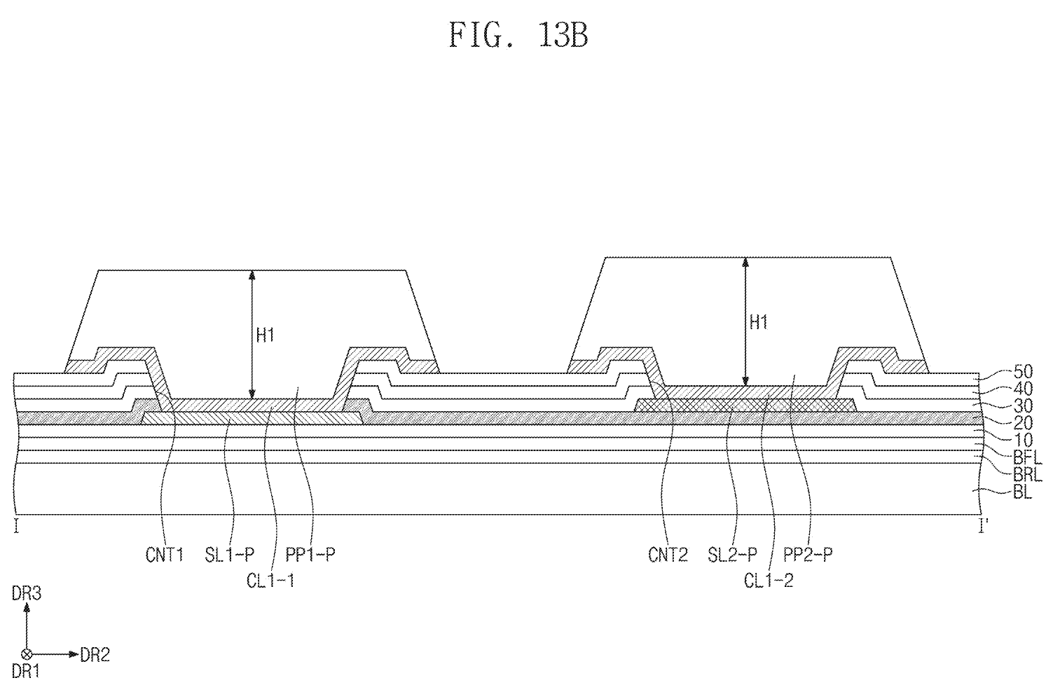

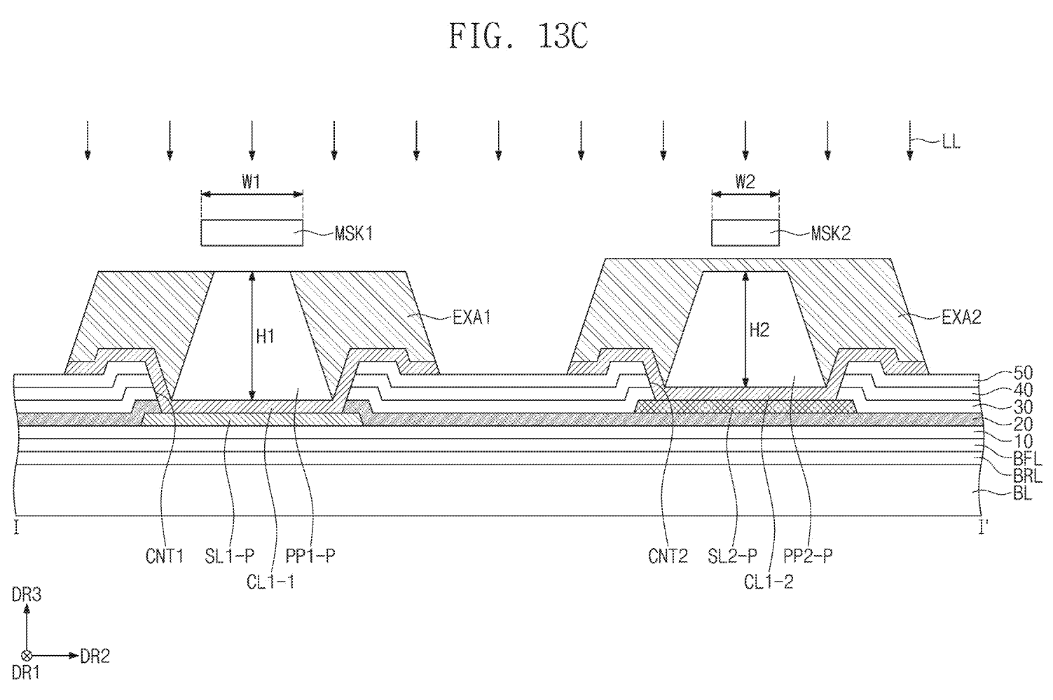

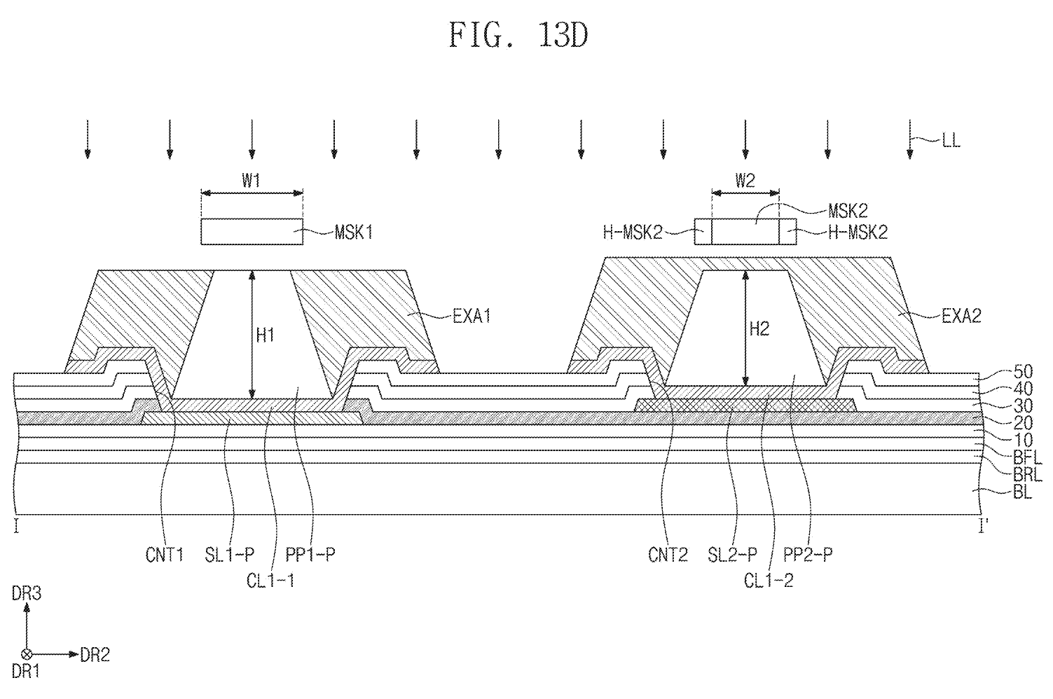

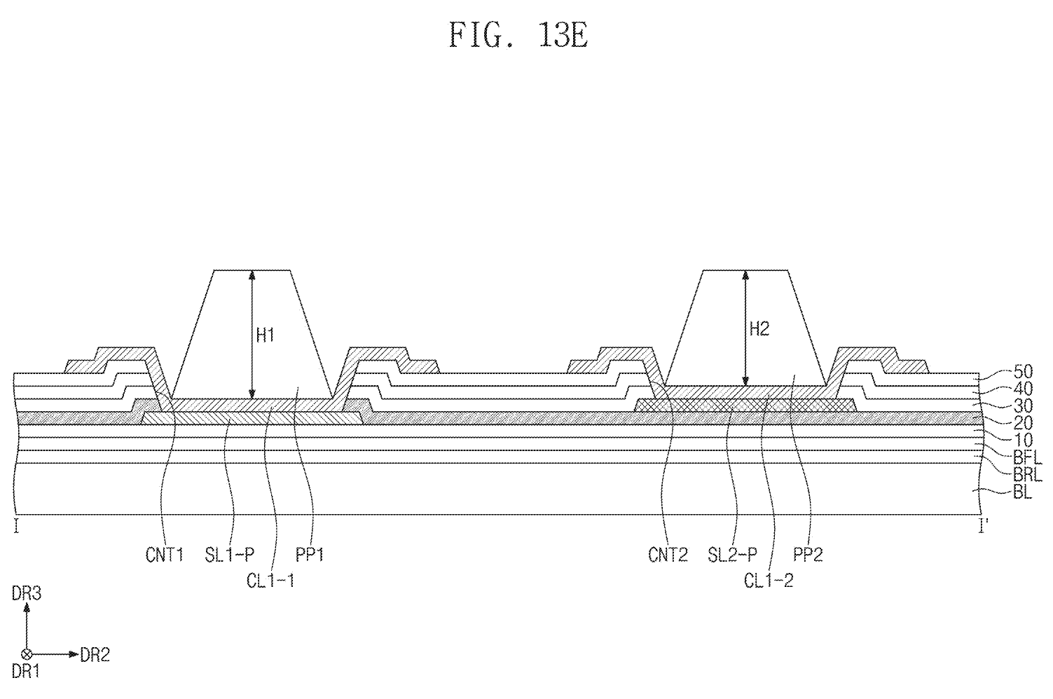

FIGS. 13A to 13E are cross-sectional views of processes of a method of manufacturing the display panel according to one or more embodiments of the present disclosure.

FIG. 13A schematically shows a process of forming the first insulating pattern PP1 and the second insulating pattern PP2 based on the cross-section of the pad area taken along the line I-I’ of FIG. 10. FIG. 13A shows the state before the forming of the first insulating pattern PP1 and the second insulating pattern PP2 on the first-first conductive pattern CL1-1 and the first-second conductive pattern CL1-2, respectively.

As shown in FIG. 13B, a preliminary first insulating pattern PP1-P is formed on the first-first conductive pattern CL1-1, and a preliminary second insulating pattern PP2-P is formed on the first-second conductive pattern CL1-2. The preliminary first insulating pattern PP1-P covers the first-first conductive pattern CL1-1, and the preliminary second insulating pattern PP2-P covers the first-second conductive pattern CL1-2. The preliminary first insulating pattern PP1-P and the preliminary second insulating pattern PP2-P may include a positive photoresist.

FIGS. 13C and 13D show processes of patterning the preliminary first insulating pattern PP1-P and the preliminary second insulating pattern PP2-P. Referring to FIG. 13C, a first mask MSK1 may have a width W1 that is greater than a width W2 of a second mask MSK2. Due to diffraction of a light LL, a first exposure area EXA1 of the preliminary first insulating pattern PP1-P may be formed, and a second exposure area EXA2 of the preliminary second insulating pattern PP2-P may be formed. The first exposure area EXA1 may have a size that is smaller than a size of the second exposure area EXA2 due to a difference in width between the first mask MSK1 and the second mask MSK2. In addition, the second mask MSK2 may have a shape that is different from that of the first mask MSK1, and the second mask MSK2 may have a shape that provides a larger exposure area to light compared to the first mask MSK1.

Referring to FIG. 13D, a half-tone mask H-MSK2 may be provided on the preliminary second insulating pattern PP2-P. The half-tone mask H-MSK2 may be applied to opposite sides of the second mask MSK2, and thus, a width W1 of the first mask MSK1 should be greater than a width W2 of the second mask MSK2. Similar to FIG. 13C, the size of the first exposure area EXA1 may be smaller than the size of the second exposure area EXA2 due to the difference in width between the first mask MSK1 and the second mask MSK2.

Referring to FIG. 13E, a process of patterning the first insulating pattern PP1 and the second insulating pattern PP2 by a photolithography process is shown. Through the process of FIGS. 13C or FIG. 13D, the height H2 of the second insulating pattern PP2 may be less than the height H1 of the first insulating pattern PP1.

Although the embodiments of the present disclosure have been described, it is understood that the present disclosure should not be limited to these embodiments but various changes and modifications can be made by one ordinary skilled in the art within the spirit and scope of the present disclosure as hereinafter claimed.

Therefore, the disclosed subject matter should not be limited to any single embodiment described herein, and the scope of the present present disclosure shall be determined according to the attached claims, with functional equivalents thereof to be included therein.

What is claimed is:

1. A display panel comprising:
a base layer;
at least one insulating layer above the base layer and comprising a first insulating layer;
a first pixel above the base layer;
a second pixel above the base layer;
a first signal line electrically connected to the first pixel and comprising a first pad portion that is not above the first insulating layer;
a second signal line electrically connected to the second pixel and comprising a second pad portion that is above the first insulating layer;
a first signal pad connected to the first signal line, and comprising a first-first conductive pattern contacting the first pad portion, a first insulating pattern above the first-first conductive pattern, and a second-first conductive pattern above the first insulating pattern and connected to the first-first conductive pattern; and
a second signal pad connected to the second signal line, and comprising a first-second conductive pattern contacting the second pad portion, a second insulating pattern above the first-second conductive pattern and having a height that is less than a height of the first insulating pattern, and a second-second conductive pattern above the second insulating pattern and connected to the first-second conductive pattern.

2. The display panel of claim 1, wherein the first pad portion is electrically connected to the first-first conductive pattern via a first contact hole defined through the at least one insulating layer, and
wherein the second pad portion is electrically connected to the first-second conductive pattern via a second contact hole defined through the at least one insulating layer.

3. The display panel of claim 1, wherein the first signal pad and the second signal pad are arranged in a same row and spaced apart from each other.

4. The display panel of claim 1, wherein a portion of the first insulating layer is between the first pad portion and the first-first conductive pattern.

5. The display panel of claim 1, wherein a difference between the height of the first insulating pattern and the height of the second insulating pattern is equal to a thickness of the first insulating layer.

6. The display panel of claim 1, wherein the first insulating layer has a thickness that is greater than or equal to about 1200 angstroms and less than or equal to about 1800 angstroms.

7. The display panel of claim 1, further comprising:
a third pixel above the base layer;
a third signal line electrically connected to the third pixel and comprising a third pad portion; and
a third signal pad connected to the third signal line and comprising a first-third conductive pattern contacting the third pad portion, a third insulating pattern above the first-third conductive pattern and having a height that is greater than the height of the second insulating pattern, and a second-third conductive pattern above the third insulating pattern and connected to the first-third conductive pattern,
wherein the at least one insulating layer further comprises a second insulating layer that is under the third pad portion and that is not under the second pad portion.

8. The display panel of claim 1, wherein the first signal pad and the second signal pad extend in one direction when viewed in a plane,
wherein the first insulating pattern is provided as a plurality of first insulating patterns spaced apart from each other in the one direction, and
wherein the second insulating pattern is provided as a plurality of second insulating patterns spaced apart from each other in the one direction.

9. The display panel of claim 1, wherein the first pad portion is electrically connected to the first-first conductive pattern via a first contact hole defined through the at least one insulating layer and having a portion between the first insulating pattern and the first-first conductive pattern in plan view, and
wherein the second pad portion is electrically connected to the first-second conductive pattern via a second contact hole defined through the at least one insulating layer and having a portion between the second insulating pattern and the first-second conductive pattern in plan view.

10. The display panel of claim 1, wherein the first insulating pattern is inside the first-first conductive pattern in plan view, and
wherein the second insulating pattern is inside the first-second conductive pattern in plan view.

11. The display panel of claim 1, wherein a length of a lower surface of the first insulating pattern is greater than a length of an upper surface of the first insulating pattern, and
wherein a length of a lower surface of the second insulating pattern is greater than a length of an upper surface of the second insulating pattern.

12. The display panel of claim 1, wherein a side surface of the first insulating pattern has a slant shape and contacts the second-first conductive pattern.

13. The display panel of claim 1, further comprising an input sensor above the second-first conductive pattern and the second-second conductive pattern.

14. An electronic device comprising:
an electronic component comprising a first bump and a second bump; and
a display panel electrically connected to the electronic component, and comprising:
a base layer;
at least one insulating layer above the base layer and comprising a first insulating layer;
a first pixel above the base layer;
a second pixel above the base layer;
a first signal line electrically connected to the first pixel and comprising a first pad portion that is not above the first insulating layer;
a second signal line electrically connected to the second pixel and comprising a second pad portion that is above the first insulating layer;
a first signal pad connected to the first signal line, and comprising a first-first conductive pattern contacting the first pad portion, a first insulating pattern above the first-first conductive pattern, and a second-first conductive pattern above the first insulating pattern and connected to the first-first conductive pattern and to the first bump; and
a second signal pad connected to the second signal line, and comprising a first-second conductive pattern contacting the second pad portion, a second insulating pattern above the first-second conductive pattern and having a height that is less than a height of the first insulating pattern, and a second-second conductive pattern above the second insulating pattern and connected to the first-second conductive pattern and to the second bump.

15. The electronic device of claim 14, wherein a height at which the second-first conductive pattern contacts the first bump is substantially equal to a height at which the second-second conductive pattern contacts the second bump.

16. The electronic device of claim 14, wherein a difference between the height of the first insulating pattern and the height of the second insulating pattern is equal to a thickness of the first insulating layer.

17. The electronic device of claim 14, wherein the first pad portion is electrically connected to the first-first conductive pattern via a first contact hole defined through the at least one insulating layer, and
wherein the second pad portion is electrically connected to the first-second conductive pattern via a second contact hole defined through the at least one insulating layer.

18. The electronic device of claim 14, wherein the first signal pad and the second signal pad extend in one direction in plan view,
wherein the first insulating pattern is provided as a plurality of first insulating patterns spaced apart from each other in the one direction, and
wherein the second insulating pattern is provided as a plurality of second insulating patterns spaced apart from each other in the one direction.

19. The electronic device of claim 14, wherein the first pad portion is electrically connected to the first-first conductive pattern via a first contact hole defined through the at least one insulating layer and having a portion between the first insulating pattern and the first-first conductive pattern in plan view, and
wherein the second pad portion is electrically connected to the first-second conductive pattern via a second contact hole defined through the at least one insulating layer and having a portion between the second insulating pattern and the first-second conductive pattern in plan view.

20. The electronic device of claim 14, wherein a length of a lower surface of the first insulating pattern is greater than a length of an upper surface of the first insulating pattern, and
wherein a length of a lower surface of the second insulating pattern is greater than a length of an upper surface of the second insulating pattern.
